(19) United States
(12) Patent Application Publication
(10) Pub. No.: US 2006/0201426 A1
(43) Pub. Date: Sep. 14, 2006

(54) Reactor for Producing Reactive Intermediates for Transport Polymerization

(76) Inventors: Chung J. Lee, Fremont, CA (US); Atul Kumar, Santa Clara, CA (US); Chang Yu Liu, Cupertino, CA (US); Michael Solomensky, Fremont, CA (US)

Correspondence Address: ALLEMAN HALL MCCOY RUSSELL & TUTTLE LLP, 806 SW BROADWAY, SUITE 600, PORTLAND, OR, 97205-3335, US

(21) Appl. No.: 11/419,985

(22) Filed: May 23, 2006

Related U.S. Application Data
(63) Continuation-in-part of application No. 11/155,209, filed on Jun. 16, 2005.
Application No. 11/155,209 is a continuation-in-part of application No. 10/854,776, filed on May 25, 2004.

(51) Int. Cl. C23C 16/00

(52) U.S. Cl. 118/715

(57) ABSTRACT

A reactor system for removing a leaving group from a gas-phase precursor to form a gas-phase radical species for transport polymerization is disclosed, wherein the reactor system comprises a reactor body, a plurality of reactor passages extending at least partially through the reactor body, and a heater body disposed in each reactor passage.

### CROSS-REFERENCE TO RELATED APPLICATIONS

The present application is a continuation-in-part of, and claims priority under 35 U.S.C. § 120 to U.S. patent application Ser. No. 11/155,209, which is a continuation-in-part of and claims priority under 35 U.S.C. § 120 to U.S. patent application Ser. No. 10/854,776, the disclosures of which are hereby incorporated by reference in their entireties for all purposes.

### BACKGROUND

Poly(paraxylylene)-based (or “PPX-based”) materials have shown promise for use in many technologies, including barrier materials for the encapsulation of organic light emitting devices (“OLEDs”) and low dielectric constant materials in integrated circuits. Examples of PPX-based materials include, but are not limited to, PPX—N ((—CH₂C₆H₄CH₂—)ₙ), PPX-D ((—CH₂C₆H₂Cl₂CH₂—)ₙ), and PPX—F ((—CF₂C₆H₄CF₂—)ₙ). PPX—F may be particularly useful in such applications due to its low water vapor transport rate, low oxygen transport rate, low dielectric constant, and good thermal and dimensional stability.

One conventional approach for producing poly(paraxylylene) films is to thermally crack a dimer such as (CH₂—C₆H₄—CH₂)₂ to produce two diradical intermediates of the formula *CH₂—C₆H₄—CH₂*, where “*” denotes an unpaired electron. The dimers are then transported in the vapor phase into a deposition chamber for polymerization on a substrate surface. This process is known as the Gorham method, and is disclosed in U.S. Pat. No. 3,342,754 to Gorham.

The Gorham method is commonly used to form some types of PPX-based films, such as PPX—N and PPX-D. However, the Gorham method may be less suitable for the preparation of PPX—F films and other PPX-based films. This is at least due to the fact that the dimer (CF₂—C₆H₄—CF₂)₂ is difficult to synthesize in sufficient quantities for commercial applications. For example, U.S. Pat. No. 3,268,599 to Chow (“the Chow patent”) discloses synthesizing the dimer (CF₂—C₆H₄—CF₂)₂ by trapping the compound in a solvent. However, the solvent-trapped dimer may be difficult to use for commercial scale production needs. Furthermore, production of the dimer via this method may be prohibitively expensive.

U.S. Pat. No. 5,268,202 to Moore (“the Moore patent”) discloses utilizing copper or zinc elements inside a stainless steel pyrolyzer to generate *CF₂—C₆H₄—CF₂* intermediates from the precursor BrCF₂—C₆H —CF₂Br at temperatures of 350-400 degrees Celsius. The Moore patent describes the copper or zinc as “catalysts.” However, these metals would actually serve as reactants in this process for the formation of metal bromides, which may clog the reactor surfaces and prevent further debromination. Also, the particular metal bromides formed may migrate to deposition chamber and contaminate the wafer, and also may be difficult to reduce back to elemental metals. Furthermore, omission of these “catalysts” would require a cracking temperature over 800 degrees Celsius to completely debrominate the precursor. At these temperatures, significant amounts of organic residues, typically in the form of carbon, may accumulate in the reactor, thus harming reactor performance and requiring frequent cleaning.

Additionally, the pyrolyzer and wafer holder of Moore are disclosed as being inside of the same closed system. This may make cooling the wafer for film deposition difficult, and also may pose a risk of substrate warming during a deposition process. Depositing the PPX—F film on a warmer substrate may result in decreased yields due to lesser quantities of precursors condensing on the substrate for polymerization. This may result in the waste of significant quantities of precursor, which may greatly increase the expense of a deposition process.

### SUMMARY

A reactor system for removing a leaving group from a gas-phase precursor to form a gas-phase radical species for transport polymerization is provided, wherein the reactor system comprises a reactor body, a plurality of reactor passages extending at least partially through the reactor body, and a heater body disposed in each reactor passage.

### BRIEF DESCRIPTION OF THE DRAWINGS

FIG. 1 shows a block diagram of an exemplary embodiment of a chemical vapor deposition system.

FIG. 2 shows a schematic diagram of an exemplary embodiment of a reactor system for use with the chemical vapor deposition system of FIG. 1.

FIG. 3 shows a partially sectioned side view of an exemplary embodiment of a reactor system.

FIG. 4 shows a bottom sectional view of the embodiment of FIG. 3.

FIG. 5 shows a side sectional view of an embodiment of a heater body positioned inside of a reactor passage of the embodiment of FIG. 3.

FIG. 6 shows an isometric view of the heater body of FIG. 5.

FIG. 7 shows a side sectional view of an alternate embodiment of a heater body positioned inside of a reactor passage of the embodiment of FIG. 3.

FIG. 8 shows an isometric view of the heater body of FIG. 7.

FIG. 9 shows a partially sectioned view of an exemplary embodiment of an insulating structure positioned around the embodiment of FIG. 2.

FIG. 10 shows a magnified view of the insulating structure of FIG. 9.

FIG. 11 shows an exemplary thermal resistance diagram of the insulating structure of FIG. 9.

FIG. 12 shows a graphical representation of a variation of a surface temperature of the insulating structure of FIG. 9 as a function of a number of radiation shields and outer surface emissivity.

FIG. 13 shows a graphical representation of a variation of a heat loss from a reactor system as a function of a number of radiation shields and outer surface emissivity of the insulating structure of FIG. 9.

FIG. 14 shows a schematic diagram of another exemplary embodiment of a reactor system.

FIG. 15 shows a schematic diagram of the reactor system of FIG. 2 attached to a plurality of precursor sources.

### DETAILED DESCRIPTION OF THE DEPICTED EMBODIMENTS

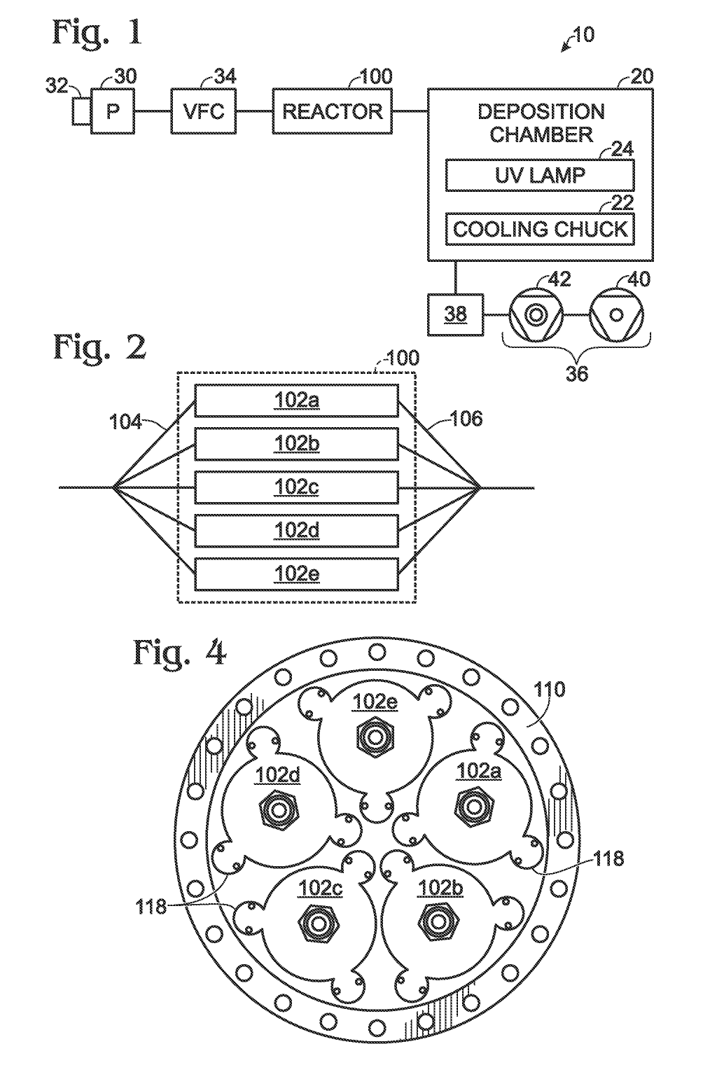

FIG. 1 shows, generally at 10, a vapor deposition system for depositing a polymer dielectric film on a substrate via transport polymerization. System 10 is at times described herein in the context of a system for depositing a PPX—F film, but it will be appreciated that the concepts set forth herein may be extended to any other suitable transport polymerization deposition system.

Vapor deposition system 10 includes a vapor deposition chamber 20, and a substrate holder 22 for holding a substrate during deposition. Deposition chamber 20 may also include an energy source, such as an ultraviolet light source 24, for various purposes, for example, for drying a substrate surface before depositing a low dielectric constant film, or for activating the polymerization of a keto-, vinyl- or halo-organosilane layer that may be deposited above or below the low dielectric constant polymer film. Exemplary organosilane materials and uses thereof are disclosed in U.S. Pat. No. 6,962,871 to Chung J. Lee and Atul Kumar, filed Mar. 31, 2004 and titled Composite Polymer Dielectric Film; U.S. patent application Ser. No. 10/816,179 of Chung J. Lee, Atul Kumar, Chieh Chen and Yuri Pikovsky, filed Mar. 31, 2004 and titled System for Forming Composite Polymer Dielectric Film; and U.S. patent application Ser. No. 10/815,994 of Chung J. Lee and Atul Kumar, filed Mar. 31, 2004 and titled Single and Dual Damascene Techniques Utilizing Composite Polymer Dielectric Film, the disclosures of which are hereby incorporated by reference.

Vapor deposition system 10 also includes a precursor source 30 for holding a precursor compound. For example, where system 10 is for depositing a PPX-F film, precursor source 30 may be configured to hold a precursor of the general formula XCF₂—C₆H₄—CF₂X′, wherein X and X′ are each leaving groups that may be removed from the precursor to generate the diradical intermediate *CF₂—C₆H₄—CF₂*. A heater 32 may be provided to heat precursor source 30 to generate a vapor pressure of the precursor within the source.

Vapor deposition system 10 also includes a reactor system 100 for converting a flow of precursor molecules into a flow of gas-phase free radical intermediates. The flow of precursor vapor into reactor system 100 may be controlled in any suitable manner. In the depicted embodiment, the flow of precursor vapor into reactor system 100 (and reactive intermediate into deposition chamber 20) is controlled by a vapor flow controller 34 and one or more valves (not shown). The outflow from reactor system 100 is directed into deposition chamber 20, where the reactive intermediates may condense on a substrate positioned on substrate holder 22 and polymerize to form a low dielectric constant polymer film. To help the reactive intermediates condense on the substrate surface, substrate holder 22 may be configured to cool the substrate surface to a suitably low temperature. Additionally, to prevent film deposition inside the gas line between reactor system 100 and the deposition chamber, the gas line and chamber wall temperatures may be heated to a temperature, for example, of 25-50° C.

Deposition chamber 20 may be maintained under a vacuum by a pumping system 36, which may include one or more low vacuum pumps 40 to pump the deposition chamber to a vacuum, and one or more high vacuum pumps 42 to maintain a desired vacuum for deposition of the polymer film. An exhaust trap or treatment system, such as a cold trap 38 or a scrubber (not shown), may be provided to treat or trap chamber exhausts.

FIG. 2 shows a block diagram of an exemplary embodiment of reactor system 100. Reactor system 100 includes a plurality of individual reactor passages 102 (individually labeled 102a, 102b, 102c, 102d and 102e). Reactor passages 102 are each configured to receive a precursor compound through an inlet 104, to convert the precursor compound into a reactive intermediate species for polymerization, and to output the reactive intermediate species via an outlet 106. The use of a plurality of individual reactor passages 102 may allow for higher reactive intermediate production rates to be achieved relative to the use of a reactor having a single reactor. Higher rates of reactive intermediate production may be desirable in situations where it is desired to deposit relatively thick films and/or to deposit films over large areas, such as in the production of large OLED displays. While FIG. 2 depicts reactor system 100 as having five individual reactor passages passage 102, it will be appreciated that reactor system 100 may have two, three, four, or more than five individual reactor passages. Furthermore, while reactor system 100 is depicted as having separate inlets 104 and outlets 106, it will be appreciated that reactor system 100 may have any suitable number of inlets and outlets. Other exemplary embodiments with different inlet and outlet configurations are described in more detail below.

In many applications, it may be desirable to form an extremely pure polymer film with low concentrations of impurities and unwanted chain terminations, cross-linking, etc. The formation of species other than the desired diradical species or the presence of other impurities may result in unwanted polymer chain branching and termination, which may lead to the growth of a polymer film with unfavorable electrical properties, unfavorable moisture/O₂ barrier properties, unsuitable thermal and/or mechanical stability, etc. It is therefore desirable for reactor system 100 to generate intermediates with substantially no unwanted side products (>99% purity). Additionally, due to the expense of precursors such as BrCF₂C₆H₄CF₂Br, it is desirable to generate radical intermediates with high efficiency (>99% yield).

Known commercial tubular thermal reactors, or pyrolyzers for converting the precursor dimer (CH₂C₆H₄CH₂)₂ to two diradical intermediate molecules have been found to be unsuitable for forming reactive intermediates from many other monomer precursors. One reason for this may be that the temperature within the commercially available reactors typically has too much positional variation. For example, when a commercially available hollow tubular pyrolyzer having a length of eight inches and an inner diameter of 1.2 inches was heated to 480 degrees Celsius under a vacuum of 10 mTorr for the removal of Br from the precursor BrCF₂C₆H₄CF₂Br, it was found that a large fraction of the interior volume of the pyrolyzer had temperatures much cooler than 480 degrees. Due to poor heat transfer under vacuum, only a small region of the inner wall in the downstream areas within the pyrolyzer was at the desired temperature. Thus, bromine atoms may not be removed from a large fraction of precursor molecules flowing through the reactor, leading to low yields of reactive intermediate.

To attempt to solve such problems, the pyrolyzer may be heated to a higher temperature, for example 800 degrees Celsius or higher, so that the temperature within the entire volume of the pyrolyzer is greater than 480 degrees Celsius. This may achieve complete removal of bromine from the precursor. However, at the higher temperatures within the pyrolyzer, other bonds besides the C—Br bonds will likely be broken. This may cause the formation of thick carbon deposits (“coke”) within the pyrolyzer, which can further insulate the center region of the pyrolyzer and make the positional temperature variation within the pyrolyzer even greater. Furthermore, the breaking of other bonds besides the C—Br bond may result in a variety of different reactive intermediates being introduced into deposition chamber 20, and thus may result in unwanted cross-linking, the formation of many polymer chain ends, and other such problems. The resulting films may have poorer thermal stability and inferior electrical properties compared to the desired films.

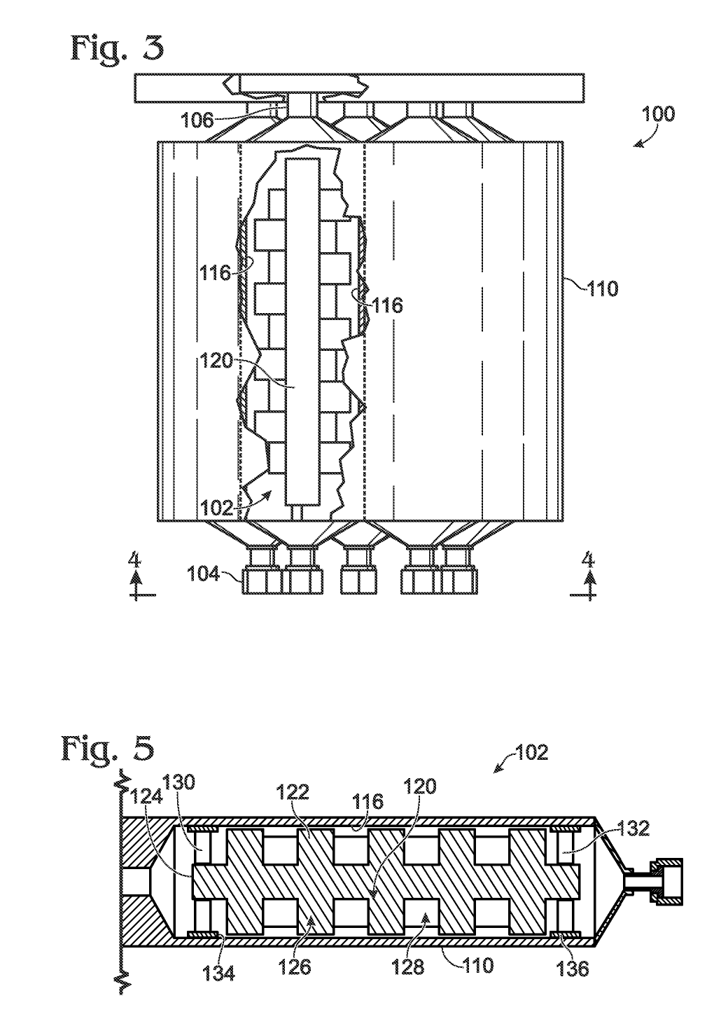

As described in more detail below, the design of reactor system 100 allows the removal of a leaving group from precursors with high efficiency and with essentially no unwanted side products allow the production of high-quality polymer via transport polymerization. FIG. 3 shows a partially sectioned view of an embodiment of reactor system 100, and FIG. 4 shows a sectional bottom view of the embodiment of FIG. 3. As depicted in these figures, reactor system 100 includes a reactor body 110 through which each reactor passage 102 extends. Each reactor passage 102 has a cylindrical configuration, and extends through the length of reactor body 110 along a cylindrical axis of reactor body. While the reactor passages 102 in the depicted embodiment extend through the entire length of reactor body 110, it will be appreciated that one or more reactor passages 102 may extend only part of the length of reactor body 110. For example, a reactor passage 102 may include an outlet and/or an inlet formed in a side wall of body 110. Furthermore, while the depicted reactor body 110 has a cylindrical configuration with a circular cross-section, it will be appreciated that reactor body 110 may have any other suitable configuration, including but not limited to oval, triangular, rectangular, polygonal, and curved cross-sectional shapes, and combinations thereof. Furthermore, while the depicted reactor system 100 includes a solid reactor body 110 through which reactor passages 102 are formed, reactor system 100 may instead include a hollow body in which separate tubular reactors are packed.

Each reactor passage 102 is defined by an inner wall 116 of reactor body 110, and includes a heater body 120 disposed therein. Reactor passages 102 are configured to be able maintain a desired vacuum, which may be, for example, on the order of approximately 0.01-2 Torr for the conversion of BrCF₂C₆H₄CF₂Br to *CF₂C₆H CF₂*. Reactor system 100 may also include one or more heating elements 118 for providing heat to reactor passages 102 and heater bodies 120. In the depicted embodiment, three heating elements 118 are positioned around each reactor passage 120. However, it will be appreciated that any other suitable number and/or arrangement of heaters may be used. Alternatively and/or additionally, heating elements may be provided around the outside of reactor body 110 for providing heat to reactor passages 102. Furthermore, in some embodiments, a heater may be provided within the interior portion of each heater body 120.

Reactor body 110 and heater bodies 120 are configured to cooperate to evenly heat precursor molecules introduced into the reactor to crack the precursor molecules with a high yield while avoiding unwanted side reactions. Furthermore, both inner walls 116 of reactor body 110 and heater bodies 120 may include a material configured to react with leaving groups on the precursor molecules, thereby lowering the energy of the cracking reaction, and thus lowering the temperature at which the cracking takes place. Such a material may also trap the leaving groups and thus help prevent contamination of the growing polymer film with leaving groups. In these embodiments, this material may also be configured to be easily regenerated between processing runs. Each of these features is described in detail below.

Reactor system 100 may be configured to process any suitable precursor from which reactive intermediates may be formed. Examples include, but are not limited to, precursors having the general formula:
X′ₘ—Ar—(CZ′Z″Y)ₙ (I)
In this formula, X′ and Y are leaving groups that can be removed to form a free radical for each removed leaving group, Ar is an aromatic group or a fluorine-substituted aromatic group bonded to m X′ groups and n CZ′Z″Y groups, and Z′ and Z″ are H, F or C₆H₅₋ₓFₓ(x=0, or an integer between 1 and 5). For example, where m=0 and n=2, removal of the leaving group y from each CZ′Z″Y functional group yields the diradical Ar(CZ′Z″*)₂. Compounds in which Z′ and Z″ are F may have lower dielectric constants and improved thermal stability. Examples of suitable leaving groups for X′ and Y include, but are not limited to, ketene and carboxyl groups, bromine, iodine, —NR₂, —N⁺R₃, —SR, —SO₂R, —OR, ═N⁺═N—, —C(O)N₂, and —OCF—CF₃ (wherein R is an alkyl or aromatic group). The numbers m and n in formula (I) may independently be either zero or an integer, and (n+m) is equal to or greater than two, up to the total number of sp² hybridized carbons in the aromatic group that are available for substitution.

Ar in formula (I) may be any suitable aromatic group. Examples of suitable aromatic groups for Ar include, but are not limited to, the phenyl moiety C₆H₄₋ₙFₙ (n=0 to 4); the naphthenyl moiety C₁₀H₆₋ₙFₙ (n=0 to 6); the di-phenyl moiety C₁₂H₈₋ₙFₙ (n=0 to 8); the anthracenyl moiety C₁₂H₈₋ₙFₙ (n=0 to 8 ); the phenanthrenyl moiety C₁₄H₈₋ₙFₙ (n=0 to 8); the pyrenyl moiety C₁₆H₈₋ₙFₙ ( n=0 to 8); and more complex combinations of the above moieties such as C₁₆H₁₀₋ₙFₙ (n=0 to 8). Isomers of various fluorine substitutions on the aromatic moieties are also included. More typically, Ar is C₆H₄, C₆F₄, C₁₀F₆, or C₆F₄-C₆F₄.

Low dielectric constant polymer film 16 may also be made from a precursor having the general formula
X′ₘArX″ₙ (II)
wherein X′ and X″ are leaving groups, and Ar is an aromatic or fluorine-substituted aromatic. The numbers m and n each may be zero or an integer, and m+n is at least two, but no greater than the total number of sp² hybridized carbon atoms on Ar that are available for substitution. For example, polyphenylene (—(C₆H₄)—) and fluorine-substituted versions thereof may be formed from a precursor having general formula (VI). Removal of the leaving groups X′ and/or X″ may create the diradical benzyne (*C₆H₄*), which can then polymerize to form polyphenylene. Other aromatic groups besides the phenyl moiety that may be used as Ar in formula (VI) include, but are not limited to, the naphthenyl moiety C₁₀H₆₋ₙFₙ (n=0 to 6); the diphenyl moiety C₁₂H₈₋ₙFₙ (n=0 to 8); the anthracenyl moiety C₁₂H₈₋ₙFₙ (n=0 to 8); the phenanthrenyl moiety C₁₄H₈₋ₙFₙ (n=0-8); the pyrenyl moiety C₁₆H₈₋ₙFₙ (n=0-8); and more complex combinations of the above moieties such as C₁₆H₁₀₋ₙFₙ (n=0-10).

In particular, some polymers with fluorine atoms bonded to sp² hybridized and hyperconjugated sp³-carbon atoms, including but not limited to PPX—F, may possess particularly advantageous thermal, chemical and electrical properties for use in integrated circuits. However, as described above, PPX—F has proven to be difficult to utilize in a commercially feasible manner for integrated circuit production. For example, the dimer (CF₂—C₆H₄—CF₂)₂ has so far proven to be difficult to synthesize in sufficient quantities for large-scale integrated circuit production. Furthermore, cracking of the monomer BrCF₂—C₆H₄—CF₂Br in a stainless steel reactor to produce the diradical *CF₂—C₆H₄—CF₂*, as disclosed in the above-described Moore patent, may result in the formation of large quantities of coke if the temperatures disclosed as necessary in the absence of a Zn or Cu “catalyst” (which are actually reactants, and not catalysts) are used.

Another problem with cracking brominated precursor molecules having fluorine atoms on hyperconjugated sp³ carbon atoms is that the C—Br bonds and the C—F bonds have cracking temperatures that are relatively close together. If the temperature within the reactor is too high or has too much variation, it is possible that either the temperature is too low in places to crack C—Br bonds, or too high in places to avoid cracking C—F bonds (or sp² hybridized C—H bonds). In either case, the result is that yields of reactive intermediates decrease while yields of unwanted contaminants increase.

One difficulty in achieving temperature uniformity is due to the difficulty of controlling heat transfer due to conductive and convective modes in the vacuum environment within a conventional thermal reactor at low pressures. Temperature uniformity may be increased by increasing the pressure within reactor passages 102, thereby improving convective heat transfer. However, this may increase the number of collisions between reactive intermediate molecules, and thus may cause reactive intermediates to bond together to form larger intermediates. These larger molecules have higher melting points than the desired reactive intermediates, and thus may condense onto a cooled wafer surface within deposition chamber 20 and form powders. This may cause the growth of a lower quality polymer film. Furthermore, the larger intermediates also may increase coke formation within the reactor.

Reactor system 100 overcomes the problem of temperature uniformity by more carefully controlling radiative heat transfer within reactor passages 102, while decreasing conductive heat transfer between heater bodies 120 and reactor body 110. Radiative heat transfer is the transfer of heat via electromagnetic energy. Because radiative heat transfer does not rely on the direct transfer of kinetic energy between colliding or coupled atoms or molecules, radiative heat may be distributed evenly throughout an evacuated volume more easily than convective or conductive heat. This may help to lessen problems with hotspots where one location within reactor system 100 is significantly hotter than another location within the reactor, and therefore may help to reduce coke formation, unwanted side reactions, etc. It will be appreciated, however, that energy may be imparted to precursor molecules via both radiation and conduction, as precursor molecules traveling through the reactor may pick up energy by colliding with inner walls 116 and with heater bodies 120, and also may absorb infrared radiation emitted by the surfaces within the reactor. Furthermore, heater bodies 120 and inner walls 116 may be formed at least partially from a material that can chemically react with the leaving groups at temperatures below the thermal cracking temperature. This may allow the precursors to be cracked at temperatures low enough to avoid significant coke formation. This feature is described in more detail below.

Specifically, reactor system 100 achieves a high level of temperature uniformity by the irradiation of heater bodies 120 with IR radiation emitted by inner walls 116. Over a short period of time, heater bodies 120 and inner walls 116 reach a condition of thermal equilibrium in which each part emits an amount of IR radiation roughly equal to what it absorbs. Careful design of reactor body 110, heater bodies 120 and heaters 118 (or other heating mechanism used to heat the reactor) may allow a substantially similar flux of IR radiation to be achieved throughout the inner volume of the reactor. Furthermore, reactor body 110 and heater bodies 120 may each be made of a material with high thermal conductivity. In this way, heat can easily spread along reactor body 110 and heater bodies 120, further helping to maintain temperature uniformity. This may facilitate the removal of a desired leaving group with a high level of specificity with a lessened amount of unwanted side reactions. Furthermore, because the temperatures of the surfaces within the reactor system are substantially similar, fewer problems with hotspots and the associated coke formation may be encountered.

The surface finish of inner walls 116 and heater bodies 120 may affect the emissivity of the surfaces. As such, a rough surface can be used on heater bodies 120 and/or inner walls 116 to increase the emission of radiation energy and thereby increase heat transfer. However, this may increase deposits in certain locations, and therefore smooth surfaces may be used in an alternative embodiment.

Referring again to FIGS. 3 and 4, each reactor passage 102 is shown as having a cylindrical shape. While this example shows cylindrical reactor passages, other suitable geometries may be used if desired, including but not limited to oval, square, hexagonal, or other polygons. Reactor passages 102 and reactor body 110 may have any suitable any shape or configuration that provides the desired precursor residence time and temperature control under vacuum conditions described herein. The description and equations described below provide further details of how varying geometry, temperature, mass flow rate, etc., can affect the system and reactor design.

FIG. 5 shows a side sectional view of one of reactor passages 102. The depicted heater body 120 includes a plurality of fins 122, and a core 124 which supports the fins and from which the fins radiate. Much of the radiant energy emitted by inner wall 116 is absorbed by core 124 of each heater body 120. This absorption of radiant energy, combined with conductive heat transfer within core 124, heats core 124 substantially evenly along its length. This heat is conductively transferred through the core and into fins 122, where it is radiated outwardly toward the container and other fins. In this manner, core 124 acts as a sort of heat sink that directs heat to fins 122 for radiation. Fins 122 also absorb energy radiated by inner wall 116, although possibly to a lesser extent than core 124.

As described below, in one example, six radial fins 122 (a “set” of fins) are positioned around core 124 in a radial direction at substantially equal angle increments. Also, in this example, nine sets of fins are positioned along the axis of core 124, providing a total of 54 fins. The fins are shown as rectangular in shape, however various other shapes could be used, if desired, including but not limited to half circles, trapezoids, etc. Furthermore, either a greater or lesser number of sets of fins may be used if desired.

The depicted arrangement of fins 122 helps to achieve a high degree of temperature uniformity within reactor passages 102, on the order of ±10-20° C. Specifically, the angle between fins can be selected to provide a desired amount of radiation absorption and a desired pattern of emission, thereby providing a desired temperature profile in the reactor. The angle between the fins can also be selected so that as the precursors flow through the reactor, the mean free path is such that the molecules will collide with the large surface area side of the fins (or with inner walls 116 or cores 124), to enable heat transfer to precursors, and to enable a desired chemical reaction with the surfaces within reactor passages 102 to take place. Further, by placing the fins with the narrow edge facing the direction of flow, a low flow restriction is obtained, thereby enabling the desired throughput in a compact system. This also illustrates the advantage of varying the fin locations from one radial set to the next, as the number of fins can be reduced while still providing the desired reaction capability.

Fins 122 may be spaced inside the reactor to create an alternating heating and mixing zones 126 and 128 inside the reactor, as shown in FIG. 5. The term “heating zones” as used herein signifies the surface area of fins 122 used for transferring thermal energy to precursor molecules as the molecules collide with the fins. The term “mixing zones” implies the space between the fins in which precursor and intermediate molecules are mixed by the fluid flow patterns created by fins 122.

Furthermore, reactor system 100 may include multiple heating zones of different temperatures (not shown) to help prevent gas choking (i.e. a significantly impeded gas flow) within the reactor. Gas choking of reactive intermediates or other reaction products inside reactor system 100 may contribute to the creation of excess coke formation due to long exposure of these chemicals at high temperature. One approach to avoid or reduce this formation uses a multiple-zone heater design, for instance, having a preheating and a cracking zone (not shown). The preheating zone may have a longer path length and/or a cooler temperature than the cracking zone. Inside a preheating zone, the precursors are warmed up to a temperature close to the desired cracking temperature. Once the precursors in the pre-heater reach a desired temperature, the heated precursors can then be quickly released into, or flow into, a second heating zone for cracking. Using such a two-zone heater, the precursor and reactive intermediate molecules may spend less time in the higher cracking zone, which may help to reduce excess carbon formation inside the reactor. Thus, by reducing the heating path and temperature variation in the cracking zone of a reactor, chemical conversion efficiency can be maximized with lower amounts of carbon formation.

FIG. 5 also shows one exemplary method of coupling heater bodies 120 to reactor body 110. In this embodiment, the depicted heater body 120 is in contact with inner wall 116 only at its ends, and is held in position within container via coupling devices 130 and 132. Coupling devices 130 and 132 locate and secure heater body 120 in each reactor passage 102, thereby allowing a desired gap to be maintained between the ends of fins 122 and the interior wall of container 116. This gap provides a substantial degree of conductive insulation between heater body 120 and inner wall 116, thereby allowing the radiative energy transfer to provide a more uniform temperature profile in reactor system 100 and avoiding hot and cold spots within reactor passages 102 that may be detrimental to the performance of reactor system 100.

Coupling devices 130 and 132 may each contact thermally insulating barriers 134 and 136, respectively, within reactor passages 102, which may further help to reduce conductive heat transfer between reactor body 110 and heater body 120. In an alternative embodiment, insulators 134 and 136 are removed and coupling devices 130 and 132 are constructed of insulating material, such as a ceramic material, to reduce heat transfer by conductance. However, in some embodiments, a small portion of heater body 120 may be in thermally conductive contact with inner wall 116, as described below with regard to FIG. 7.

By substantially conductively insulating coupling devices 130 and 132 with thermal barriers 134 and 136 and with the gap between fins 122 of heater body 120 and inner wall 116, the primary mode of heat transfer between inner wall 116 and heater body 120 is made to be radiative. Furthermore, careful design of the configuration of reactor passage 102 and heater body 120 helps to control the distribution of heat in these parts and achieve a substantially similar flux of thermal radiation throughout the volume of each reactor passage 102. This allows reactor system 100 to produce highly pure intermediate at a high yield with relatively low coke formation.

The gap between the ends of fins 122 and inner wall 116 in each reactor passage 102 may have any suitable dimensions. In some embodiments, the gap between fins 122 and inner wall 116 has a distance of between approximately 0.06 and 0.08 inch, and more specifically approximately 0.068 inch, although various other size gaps can be used, such as, for example: 0.1 inch, 0.01-0.05 inch, 0.06-0.1 inch, etc.

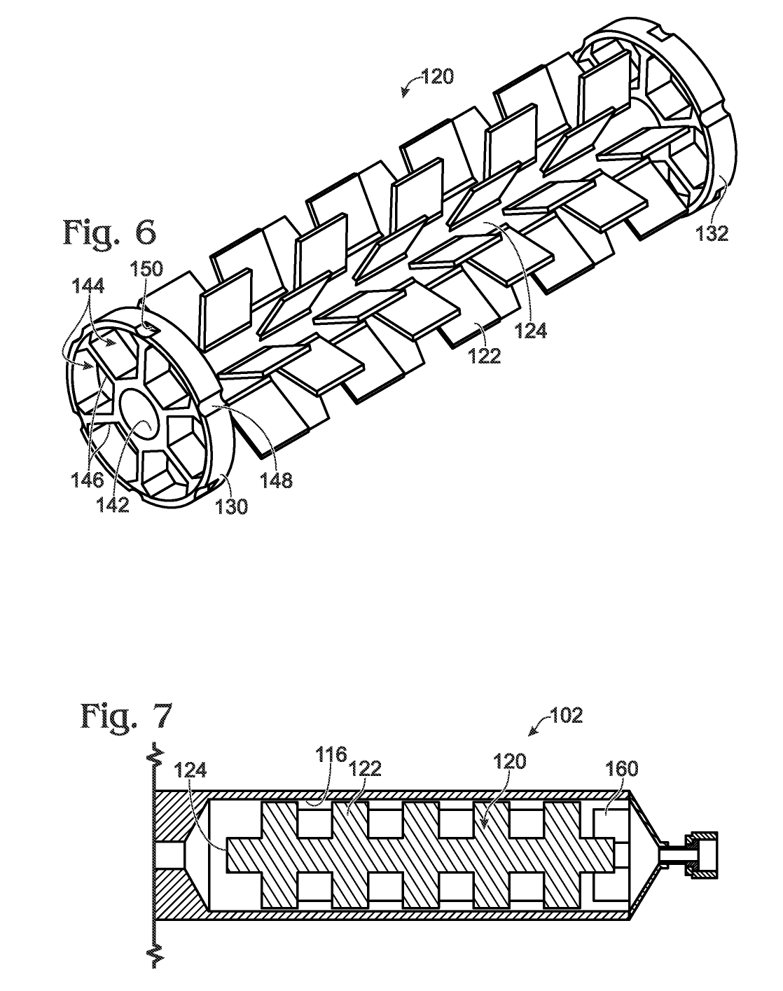

Coupling devices 130 and 134 are configured to provide support for heater body 120 in all radial directions. This allows reactor system 100 to be mounted in substantially any orientation without causing fins 122 to come into thermal contact with inner walls 116 within each reactor passage 102. FIG. 6 shows an isometric view of heater body 120 from FIG. 5 is shown with coupling devices 132 and 134. Further, an exemplary configuration of fins 122 is shown. In this example, nine sets of radial fins are used, with each set equally positioned about the diameter of heater body core 124. The nine sets are also equally spaced axially along the length of heater body 120. In the example shown in FIG. 6, the rear edge position of one set of fins along the axial length aligns with front edge of the next set of fins, although the two sets are rotationally offset from each other. Each set of fins has six radial fins, for a total of fifty-four fins in this example.

Fins 122 are positioned to provide efficient radiant energy absorption, emission and transfer. In the example of FIG. 6, each radial set of fins contains six equally spaced fins radially spaced by 60 degrees. Further, every other radial set of fins is offset by an angular increment of half the angular spacing of the fins, thirty degrees in this case. However, other spacing could be used. For example, each set of fins could be offset by fifteen degrees from the previous set, or by any other suitable angle. Each fin of the depicted embodiment is a thin rectangular section protruding with the thin edge facing the flow direction, thereby providing low flow restriction.

While this example shows each radial fin extending outward at ninety degrees relative to the shaft, other angles could be used. For example, the fins could be angled to slant to one side at an angle of forty-five degrees, or be positioned tangential to core 124. Also, different sets of fins could be positioned at a different relative angle to the shaft.

Coupling devices 130 and 132 are shown as cylindrical sections with a center hole 142 for mounting to core 124. Further, coupling devices 130 and 134 each has a plurality of sectional holes 144 (six of which are shown in the depicted embodiment) separated by walls 146 to permit passage of precursor and reactive intermediate molecules through the coupling devices 130 and 132. In the depicted embodiment, the internal walls of coupling devices 130 and 132 align with one of the fin sets, which may help to reduce gas choking. However, it will be appreciated that the internal walls of coupling devices 130 and 132 may have any other suitable orientation. As discussed above, coupling devices can be made from materials with low thermal conductivity to reduce conductive heat transfer from heater body core 124 to inner walls 116 of reactor body 110. Coupling devices 130 and 132 may have one or more recess areas (full recess 148 and partial recess 150), as illustrated in FIG. 6, for aligning the coupling devices and fixing the heater body 120 within reactor passages via complementary tabs (not shown) extending from inner walls 116.

Referring now to FIG. 7, an alternative embodiment is illustrated with an additional set of fins 160 is provided on heater body 120 to couple heater body 120 to an inlet or outlet of each reactor passage 102. In this embodiment, additional fins 160 may be coupled to the inlet or outlet by welding, or by any other suitable method. This allows heater body 120 to be mounted within container 116 while being wholly supported by either inlet 104 or outlet 106. While this connection may allow some thermal conductance between additional fins 160 and reactor body 110, additional fins 160 can be designed such that the effect is minor compared to the radiant heat transfer between container 116 and heater body 120 to reduce this conductive heat transfer. For example, additional fins 160 may be made of a material having a relatively low thermal conductivity, and/or the area of contact between additional fins 160 and reactor body 110 may be minimized. For example, in the depicted embodiment, the use of only three additional fins 160 positioned one hundred twenty degrees may help to reduce the surface contact between heater body 120 and reactor body 110 relative to the use of a greater number of additional fins. However, it will be appreciated that any other suitable arrangement may be used.

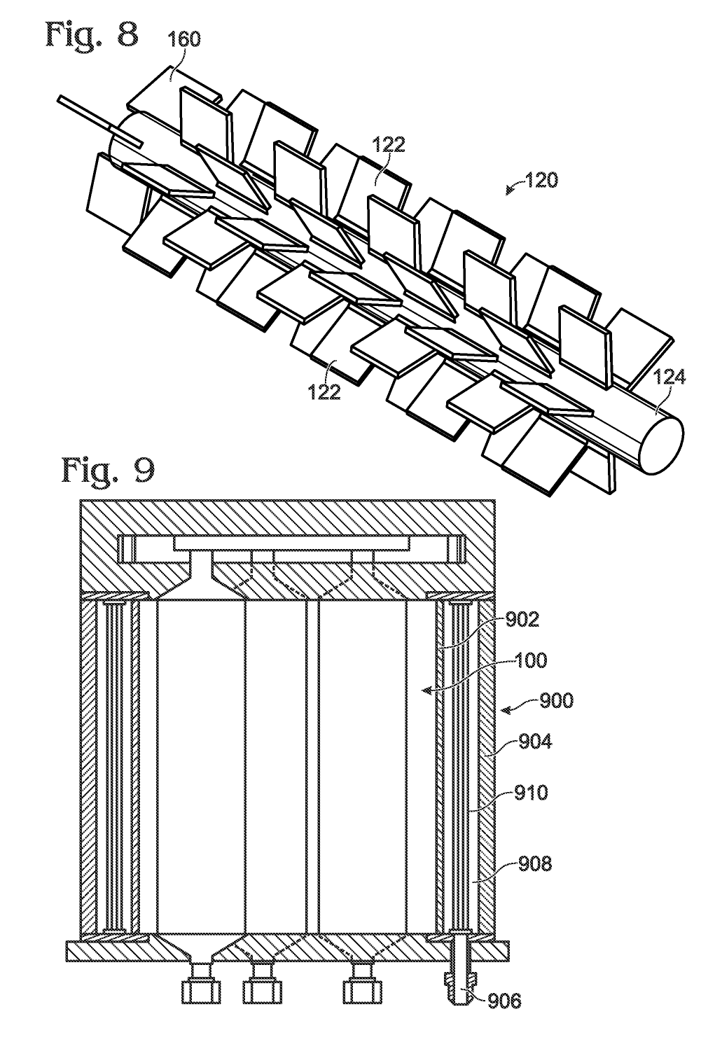

Referring now to FIG. 8, an isometric view of heater body 120 from FIG. 7 is shown with additional fins 160. As illustrated in FIG. 8, fins 160 are positioned at an end of the heater body core 124, with an angle of approximately one hundred twenty degrees between adjacent fins. The radial height, axial width, and thickness of the depicted additional fins 160 are substantially the same as fins 122, although they could be modified, if desired.

Reactor passages 102 and heater bodies 120 may be configured to provide a desired surface-to-volume ratio of internal surface area for reaction to provide a compact and effective design. For example, each reactor passage 102 may have a volume of less than or equal to approximately 60 cm³, and a surface area of 300 cm²-500 cm² (including heater body 120). In another embodiment, the volume of each reactor passage 102 is a least 10 cm³ and the total interior surface area is at least 1000 cm². It will be appreciated that these dimensions are merely exemplary, and that reactor passages 102 may have any other suitable volumes and internal surface areas, including volumes and/or surface areas either greater than or less than these examples.

Fins 122 may have any suitable dimensions. In one example, fins 122 have a thickness of approximately 0.081 inch, a radial height of approximately one inch, and a width of approximately one inch. Thus, in this case, the thickness is less than both the height and width. Further, in the depicted embodiment, approximately a one-inch gap is provided between sets of fins at the same radial position, and adjacent sets of fins (that are radially offset) have substantially no axial gap between them. While these dimensions provide an example, the dimensions may vary depending on a number of factors, including the desired flow throughput and allowed temperature variation within the reactor. Details on calculations of reactor geometries and flow characteristics are given in the above-incorporated U.S. patent application Ser. No. 11/155,209.

Also, while fins 122 are shown as having a substantially constant thickness and width along the flow direction, these dimensions may also vary along this direction. For example, the fins could have a partial or total wedge shape, such that the upstream thickness is less than the downstream thickness (or vice versa). Also, the radial height could increase along the flow direction. Further, different fins could be made with different axial widths. In still another alternative, the heater body 120, including fins 122, may take the form of a porous metal. In yet another embodiment (not shown), fins may be provided that traverse the length of the reactor and the heater body core, spiraling about 90-120 degrees along the length of the core in one example.

As mentioned above, at least some interior surfaces of reactor passages 102 may be made of a material that is capable of undergoing a chemical reaction with the leaving group (or groups) on the precursor molecules to generate the reactive intermediates for transport polymerization. In a traditional thermolytic reactor (or pyrolyzer), precursors gain thermal energy during heating by colliding with heated surfaces inside of reactor system 100. Once a precursor molecule acquires sufficient thermal energy to meet or exceed the energy of activation, thermal cracking or breakage of the chemical bonds occurs. However, the use of a metal reactant may allow cracking of a precursor at a much lower temperature than in a pure thermolytic reactor. For example, in the absence of a metal reactant, the di-bromo PPX—F precursor thermally cracks at approximately 680° C. However, iron reacts with the di-bromo precursor when the interior iron surface temperature reaches about 420° C., nickel reacts with the precursor at around 480° C., and copper reacts with the precursor at around 320 to 350° C. under a few mTorr of pressure.

In the discussion below, the term “metal reactant” is used to denote a metal capable of undergoing a chemical reaction with a leaving group on the precursor. Such a metal may be a catalyst, in that the metal is regenerated at a temperature lower than the reactor operating temperature, or may be a reactant that binds the leaving groups until a later regeneration step at a higher temperature and/or under a different gaseous environment. In either case, the presence of the metal reactant may lower the activation energy of the precursor cracking reaction, thereby allowing the reactor to be run at a lower temperature. This may help to avoid coke formation within reactor passages 102, may improve yields of reactive intermediates, and may help to decrease unwanted side reactions. Typically, the metal reactant is of a high purity to avoid the formation of any unwanted contaminant compounds.

Various other terms are used are used below to describe the chemical characteristics of the metal reactant. Some of these terms are as follows:

A “reacted metal reactant” as used herein is a metal that has reacted with a precursor to generate a desired intermediate. Where the leaving group is a halide, this term may be used to describe the metal halide resulting from the reaction.

A “reaction temperature” (Tᵣ) is a temperature at which a leaving group reacts with a metal reactant within a reactor in a sufficient quantity to produce a commercially useful amount of reactive intermediate.

A “regenerating temperature” (T_{rg}) as used herein is a temperature capable of regenerating a metal reactant from a reacted metal reactant.

A “regenerating gas” as used herein is a gas capable of regenerating a metal reactant from a reacted metal reactant (or from an otherwise oxidated metal reactant, as described in more detail below). In one embodiment, a regenerating gas or gas mixture (for example, hydrogen and argon) is used to regenerate a metal reactant from a metal halide. In another embodiment, a regenerating gas is used to regenerate a metal reactant from another oxidized metal reactant, such as a metal oxide.

Where a metal reactant is used inside of reactor passages 102, the reactive intermediates are generated by a chemical reaction between the leaving group and the metal reactant at a reaction temperature Tᵣ. For instance, many of the above-disclosed di-bromo precursors can react with a metal reactant at a suitably low Tᵣ to avoid significant coke formation and to generate the desired reactive intermediate. This reaction is illustrated in equation (1) as follows. In this equation, Y is a halogen; Z, Z′, Z″ and Z′″ are each a hydrogen, a fluorine, an alkyl, and/or an aromatic; and Ar is an aromatic.
nYZZ′CArCZ″Z′″Y+nM→n*ZZ′CArCZ″Z′″+nMY₂ (1)

The metal bromide of reaction (1) may be regenerated to increase the amount of surface area with reactor passages 102 that can be used for further conversion of precursors into intermediates. Regeneration may happen spontaneously where T_{rg} (or a decomposition temperature T_{d}) is below Tᵣ, or may be accomplished as needed by a suitable regeneration reaction performed at an effective T_{rg}. Reaction (2) illustrates this principle in the context of the reduction of the metal halide product of reaction (1) with hydrogen, as follows:
MY₂+H₂(g)→M+2HY(g) (2)
In the particular example of NiBr₂, the reaction thermodynamics for reaction (2) are as follows. At a regeneration temperature T_{rg} of 500° C., the regeneration reaction enthalpy (“dH”)=−130.4 kJ/mol, the Gibb's Free Energy (“dG”)=20.3 kJ/mol, and the reaction constant k=4.23E−2.0. It is noteworthy that that H₂ and HY are each in a gas phase.

Similarly, the metal halide MY₂ also may be regenerated in come cases by heating to a decomposition temperature T_{d} according to reaction (3), as follows:
MY₂→M+Y₂(g) (3)

In considering a material to be used as a reactive metal within reactor passages 102, at least four criteria may be considered. First, the effective reaction temperature Tᵣ between the precursor and the metal should be under 800° C. (and preferably 700° C.) under a vacuum ranging from 0.001 to a few Torr for the conversion of BrCF₂C₆H CF₂Br to *CF₂C₆H₄CF₂*. Second, in some embodiments, a material with a T_{d} equal to or lower than the effective Tᵣ may be selected. Although not wanting to be bound by theory, under this ideal condition, the metal is a catalyst. Third, a metal whose halide has a regenerating temperature T_{rg} above, or approximately equal to, Tᵣ may be selected. In some embodiments, T_{rg} is not more than 400° C., and in others, not more than 200° C. above the Tᵣ. In these embodiments, the leaving group remains bonded to the reactive metal until the reactive metal is regenerated in a later step. Fourth, the melting temperature Tₘ of the metal halide may be at least 100 to 200, and preferably 300 to 400° C., higher than the Tᵣ. A metal halide that has a Tₘ too close to the reaction temperature Tᵣ may not be stable inside reactor passages 102, and may thus tend to migrate or diffuse outside the reactor and contaminate the growing film.

Various metals that may be suitable for use as a metal reactant in conjunction with the precursor with a bromine leaving group include Ti, Cr, Fe, Co, Ni, Cu, Zn, Ta, W, Pt, Au, and Ag.

Au and Pt bromides are self-regenerating at temperatures above the T_{d} (e.g. 115 and 250° C., respectively) of their reaction products, Au and Pt may be utilized as catalyst-style reactants when using a di-bromo precursor. In addition, since Pt and Au are noble metals, organic residues inside reactor passages 102 can be removed using oxidative processes without causing oxidation of the Au and Pt. For example, a reactor 202 with Pt interior surfaces operated at temperatures from 280 to 400° C. promotes coke formation at a relatively low rate during leaving group removal, and also causes automatic regeneration of the metal by decomposition of the metal bromide. Periodically passing oxygen through the reactor at a temperature of over 400° C. and then purging with an inert or reducing gas can remove organic residue from inside the reactor. However, gold and platinum may be prohibitively expensive for use in commercial-scale reactors.

Fe and Ti may be used to remove bromine leaving groups at temperatures around 680 to 700° C. and 500 to 550° C., which are near the respective decomposition temperatures T_{d} of Fe- and Ti-bromides, respectively. However, it is important to take note that when reactor temperatures are maintained above 500° C. over time, “coke” formation can be expected. Consequently, a periodic oxidative decomposition step to remove organic residues may be needed when Fe or Ti metal reactants are used.

Cr or Ni may also be suitable for use as metal reactants. Furthermore, these metals react with the di-bromine precursors at lower temperatures than iron and titanium, and thus may help avoid coke formation. For example, Ni reacts with di-bromine precursors, such as (Br—CZZ′-Ar—CZ″Z′″-Br), at reaction temperatures Tᵣ of approximately 480° C. or above. This may be low enough to avoid high rates of coke formation. Furthermore, nickel bromide can be effectively reduced to nickel using as little as 4 to 10% of hydrogen in argon (or other inert gas) at regenerating temperatures T_{rg} ranging from 500 to 650° C. for few minutes. Additionally, nickel bromide has a melting temperature Tₘ as high as 963° C., and thus is very stable inside the reactor during the debromination and regeneration reactions.

However, the Ni tends to oxidize when oxygen is used to clean organic residues from inside reactor passages 102. One way to extend the life span of the nickel within reactor passages 102 may be to use the reactor at about 480° C. for generation of intermediates from di-bromo precursors and then regenerate the nickel from the nickel bromide at 600° C. or above using hydrogen. At 480° C., the coke formation rate is relatively low if the reactor is designed carefully and the residence time of the precursor is short, because coke formation normally starts at higher than 450 to 480° C. under desirable feed rates for precursors.

As mentioned above, Zn, Cu, Co, Al, Ag, and W may also be suitable metal reactants for the cracking of the above-mentioned precursors. In particular, Zn and Cu may be suitable for use in the deposition of barrier layers in OLEDs, coatings for medical devices, and other such applications where some amount of metal contamination in the growing film does not pose problems with device reliability, as the bromine salts of these metals may have melting points relatively close to the reactor system operating temperatures.

In yet other embodiments, a multiple step regeneration process may be used to regenerate the reacted metal reactant. These are shown in the following reactions (4) and (5):
MY₂+X₂(g)→MX₂+Y₂(g); k=k₁ (4)
MX₂+H₂(g)→M+2XH(g); k=k₂ (5)
wherein M is a transition metal such as Ni; Y═Cl, Br or I; and X is fluorine. For the specific case where MY₂ is nickel bromide, the thermodynamics of these reactions at 500° C. are as follows: dH=−416 kJ/mol; dG=−398 kJ/mol; and k₁=8.2E26 for reaction (4); and dH=106 kj/mol, dG=−17.7 kj/mol and k₂=1.6E1.0 for reaction (5). It is noteworthy that that X₂, Y₂, H₂ and HX are all in a gas phase.

Another example of a multi-step regeneration process is shown as a two-step process in reactions (6) and (7). This process may be used where reaction (6) is used to oxidize organic residues, and where reaction (7) is then used to reduce metal oxides to regenerate the metal reactant.
mMY₂+nX₂(g)→MₘX₂ₙ+mY₂; k=k₃ (6)
MₘX₂ₙ+2nH₂→mM+2nH₂X(g); k=k₄ (7)
wherein M is a transition metal such as Ni; Y is Cl, Br or I; and X is oxygen. For the specific case of NiBr₂ at 500° C. (and where m=1 and n=1), the reaction thermodynamics are as follows: dH=0.33 kJ/mol; dG=−31.33 kJ/mol and k₃=1.29E2 for reaction (6); and dH=−9.2 kj/mol, dG=−35.2 kj/mol and k₄=2.39E2.0 for reaction (7). For the specific case of FeBr₂ at 600° C. (and where m=2 and n=1.5): dH=−271kj/mol, dG=−250kj/mol and k₃=9.8E14 for reaction (6); and dH=69.4 kj/mol, dG=−5.3 kj/mol and k₄=2.06 for reaction (7). It is noteworthy that X₂, Y₂; H₂ and HX are each in a gas phase.

The oxidative cleaning reaction (6) may be performed in any suitable manner. One suitable method for cleaning the organic residue includes heating reactor passages 102 and heater bodies 120 to a desired temperature with an energy source; introducing oxygen into reactor passages 102; burning the organic residue with the heated gas to give an oxidized gas; and discharging the oxidized gas from reactor passages 102. During the cleaning process, the inside temperature of reactor passages 102 is typically heated to at least 400° C. The gas supply used to clean reactor passages 102 is typically pressurized oxygen, and may be added to reactor passages 102 to a pressure in the range of approximately 1 to 20 psi, or, alternatively, to any other suitable pressure.

While cleaning the organic resides, the oxidative cleaning process also may convert the metal halide on the interior surfaces of reactor passages 102 to a metal oxide. In this case, the metal can be restored from the metal oxide by heating under a suitable reductive gas, such as hydrogen or a mixture of hydrogen with a diluent gas, as shown in reaction (7) above. Other reducing agents that can be used for the reductive reaction (7) include, but are not limited to, ammonium hypophosphite, hydrazine and borohydride. These reducing agents can be dispensed inside reactor passages 102 as an aqueous solution or as a pure liquid agent.

By comparing reactions (4), (5), (6), and (7) to reaction (2), one observes that the multi-reaction regeneration methods may be kinetically more suitable for cleaning reactor passages 202 to their high reaction constants than the single step regeneration methods. It is also noteworthy that an end point detector (e.g. a residual gas analyzer (“RGA”)) can be used to determine the completion of reactions (6) and (7) by monitoring the contents of the bromine (from reaction 6) and water (from reaction 7).

It will be appreciated that the above examples of reactor materials, cracking reactions and regeneration reactions are intended to exemplify the principles disclosed herein, and are not intended to limit the scope of the invention in any manner. One skilled in the art will appreciate that the material selection criteria for reactor passages 102 may be applied to other metals, taking into account the chemical properties of the precursor material, reactive intermediate, and leaving groups.

In some embodiments, the individual components of reactor passages 102 and heater bodies 120 are made entirely of the metal reactant. In other embodiments, the individual components of reactor passages 102 and heater bodies 120 may be made of other materials, and the surfaces of the reactor passages that are exposed to the precursor flow are at least partially coated with the metal reactant. In these embodiments, the material from which the bulk of the reactor components are made may be referred to as a substrate that supports a film, layer or plating of the metal reactant. Examples of suitable substrate materials include, but are not limited to Ni and its alloys such as Monel and Inconel, Pt, Cr, Fe, and stainless steel. Nonmetallic materials can also be used to as substrate materials. Examples of suitable nonmetallic materials include, but are not limited to, quartz, sapphire or Pyrex glass, aluminum nitride, alumina carbide, aluminum oxide, surface fluorinated aluminum oxides, boron nitride, silicon nitride, and silicon carbide. The layer of metal reactant deposited over the substrate may also help to prevent contaminants from the substrate material from contaminating a growing polymer film.

In some use environments, it may be desirable to thermally insulate reactor system 100. For example, thermally insulating reactor system 100 may help to minimize heat losses, which may result in lower power consumption and improved temperature uniformity across reactor body 110. Furthermore, it may be desirable to maintain the outer surface of a reactor system assembly (reactor system 100 plus insulation) at a temperature of lower than 65-80 degrees Celsius, for example, for safety purposes.

Wrapping reactor body 102 in an insulating material may provide sufficient thermal insulation for some purposes. However, such an approach may require a thick layer of insulating material to maintain an estimated temperature gradient of, for example, a temperature of 600 degrees Celsius from the outer surface of reactor body 110 to a temperature of 65-80 degrees Celsius at the outer surface of the insulating material. In addition, many commonly-used insulating materials generate particulate matter, and therefore may not be suitable for cleanroom use.

FIG. 9 depicts an exemplary embodiment of an insulating structure 900 configured to overcome such problems. Insulating structure 900 includes an inner wall 902, an outer wall 904, and a vacuum port 906 configured to allow a vacuum space 908 between inner wall 902 and outer wall 904 to be evacuated. Insulating structure 900 also includes a plurality of radiation shields 910 disposed within vacuum space 908.

FIG. 10 shows a magnified view of radiation shields 910. Radiation shields 910 are spaced from inner wall 902 and outer wall 904 and from each other. In the depicted embodiment, the spaces between radiation shields 910 are substantially equal in distance. However, it will be appreciated that radiation shields 910 may have any other suitable spacing, including one or more unequal spaces between the shields.

In some embodiments, radiation shields 910 and/or inner wall 902 may be made of a low emissivity material or materials to help minimize radiative losses. Furthermore, spacer materials and other materials that hold radiation shields 910 in place may also be made of a low emissivity material or materials to further help reduce radiative losses. Furthermore, the outer surface of outer wall 904 may be made at least partially of a highly emissive material or materials to reduce the external surface temperature of reactor system 100.

While the embodiment of FIG. 9 includes four radiation shields, it will be appreciated that insulating structure 900 may include either a greater or lesser number of radiation shields 910 where suitable. For example, a number of radiation shields to use to achieve a desired reactor assembly surface temperature may be determined mathematically. An example calculation is as follows. The exemplary calculations assume a diameter of vacuum space 908 of r=0.25 m; a length of the chamber along a direction of gas flow of 1=0.3 m; an emissivity of the radiation shields of ε₁=0.1; an emissivity of the internal surface of the vacuum chamber ε₁=0.1; emissivities of the external surface of the vacuum chamber of ε₀=0.9 and 0.1; a surface temperature of inner wall 902 (facing vacuum space 908) of 650 degrees C.; and an ambient temperature of 25 degrees C.

The heat transferred from the inner surface of inner wall 902 to the external surface of outer wall 904 of insulating structure 900 is equal to the heat dissipated by natural convection and radiation from the external surface of the vacuum chamber. FIG. 10 shows an exemplary thermal resistance diagram 1000 of insulating structure 900. In thermal resistance diagram 1000, Q₁ is an amount of heat present within reactor body 110, T₁ is a temperature at the inner surface of inner wall 902 of insulating structure 900 (adjacent to the outer surface of reactor body 110), T₂ is a temperature at the outer surface of outer wall 904 of insulating structure 900, Tₐ is a temperature of the surrounding air, and Tₛᵤᵣᵣ is the temperature of the surrounding atmosphere.

Based on the thermal resistance diagram shown in FIG. 10, the heat balance equation is:

$$Q = \frac{1}{N + 1} \frac{{A}_{1} σ ( {T}_{1}^{4} - {T}_{2}^{4}}{\frac{1}{{ɛ}_{1}} + \frac{1}{ {ɛ}_{1}} - 1} = hA ( {T}_{2} - {T}_{a} ) + {ɛ}_{o} A σ ( {T}_{2}^{4} - {T}_{surr}^{4} )$$

wherein ε₁=emissivity of radiation shields=emissivity of internal surface=0.1, ε₀=emissivity of external surface=0.1 and 0.9 in two different examples, A₁=surface area of single heat shield, h=heat transfer coefficient, Tₐ=air temperature=25 C, Tₛᵤᵣᵣ=temperature of surroundings=25 C, A=Area of external surface, σ=constant, and N=number of radiation shields.

The convection heat transfer rate is
Q_{conv}=(h₁A₁+h₂A₂)(T₂−Tₐ)

The convection heat transfer coefficients for the horizontal and vertical surfaces are:

$${h}_{1} = 0.54 \frac{k}{{L}_{1}} {Ra}_{1}^{0.25} = 0.54 \frac{k}{{L}_{1}} {( \frac{g β {PrL}_{1}^{3}}{{V}^{2}} )}^{0.25} {( {T}_{2} - {T}_{a} )}^{0.25}$$

$${h}_{2} = 0.59 \frac{k}{{L}_{2}} {Ra}_{2}^{0.25} = 0.59 \frac{k}{{L}_{2}} {( \frac{g β {PrL}_{2}^{3}}{{V}^{2}} )}^{0.25} {( {T}_{2} - {T}_{a} )}^{0.25}$$

wherein Ra and Pr are Rayleigh and Prandtl numbers respectively, g=acceleration of gravity, β=volumetric coefficient of thermal expansion, and υ=viscosity.

The corresponding characteristic lengths are:

$${L}_{1} = \frac{{A}_{1}}{{P}_{1}} = \frac{{D}_{2}}{2} = 0.0625 m$$

$${L}_{2} = L = 0.3 m$$

The properties of the air are (at average temperature 320 K):

$$β = \frac{1}{T} = \frac{1}{320} = 0.003 {K}^{- 1}$$

$$Pr = 0.7$$

$$v = 1.77 \times {10}^{- 5} {m}^{2} / s$$

$${T}_{a} = 25 C$$

Substituting all the numerical values into the convective heat transfer equation above, the equation becomes:
Q_{conv}=0.734(T₀−298)^{1.25}
The radiation heat loss is:

$$\begin{matrix}{Q}_{rad} = {ɛ}_{o} A σ ( {T}_{2}^{4} - {298}^{4} ) \\ = 0.1 \times ( 0.24 + 2 \times 0.049 ) 5.67 \times {10}^{- 8} ( {T}_{2}^{4} - {298}^{4} ) \\ = 1.89 \times {10}^{- 9} ( {T}_{2}^{4} - {298}^{4} )\end{matrix}$$

for the outer surface emissivity equals 0.1, and
Q_{rad}=17×10⁻⁹(T₂⁴−298⁴)
for the outer surface emissivity equals 0.9.

Likewise, the heat balance equation becomes (for ε₀=0.1):

$$\begin{matrix}\begin{matrix}\frac{1}{N + 1} 0.0996 \times \\ {10}^{- 8} \times ( {923}^{4} - {T}_{2}^{4} )\end{matrix} = 0.734 {( {T}_{2} - 298 )}^{1.25} + 0.189 \times \\ {10}^{- 8} ( {T}_{2}^{4} - {298}^{4} )\end{matrix}$$

$$and \text{,} for {ɛ}_{o} = 0.9 \text{:}$$

$$\begin{matrix}\begin{matrix}\frac{1}{N + 1} 0.0996 \times \\ {10}^{- 8} \times ( {923}^{4} - {T}_{2}^{4} )\end{matrix} = 0.734 {( {T}_{2} - 298 )}^{1.25} + 1.7 \times {10}^{- 8} \\ ( {T}_{2}^{4} - {298}^{4} )\end{matrix}$$

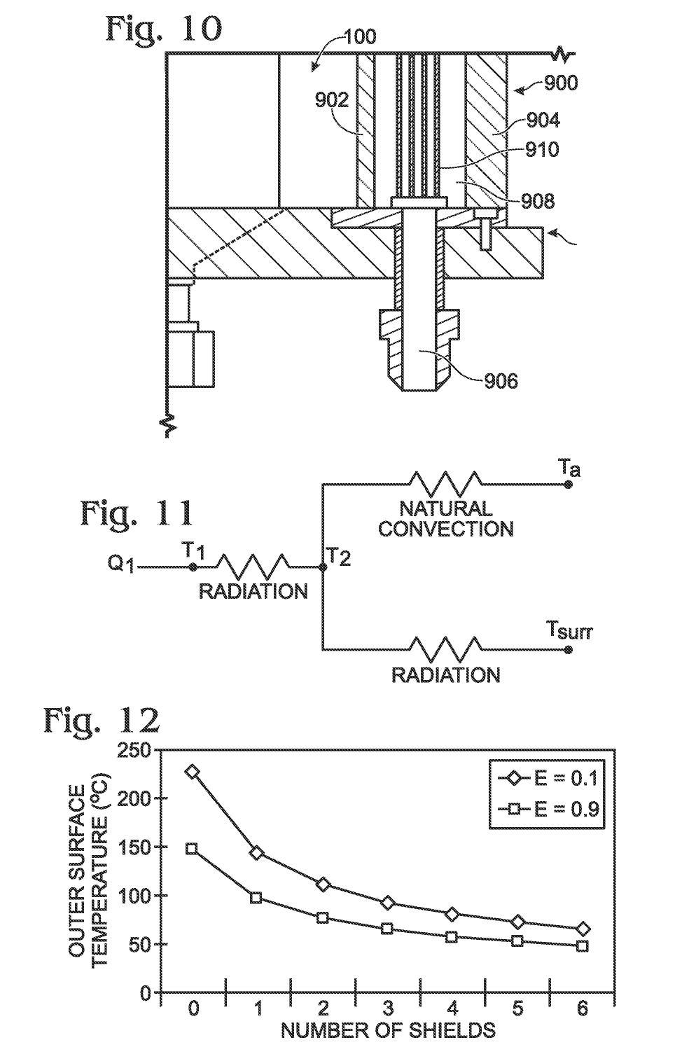

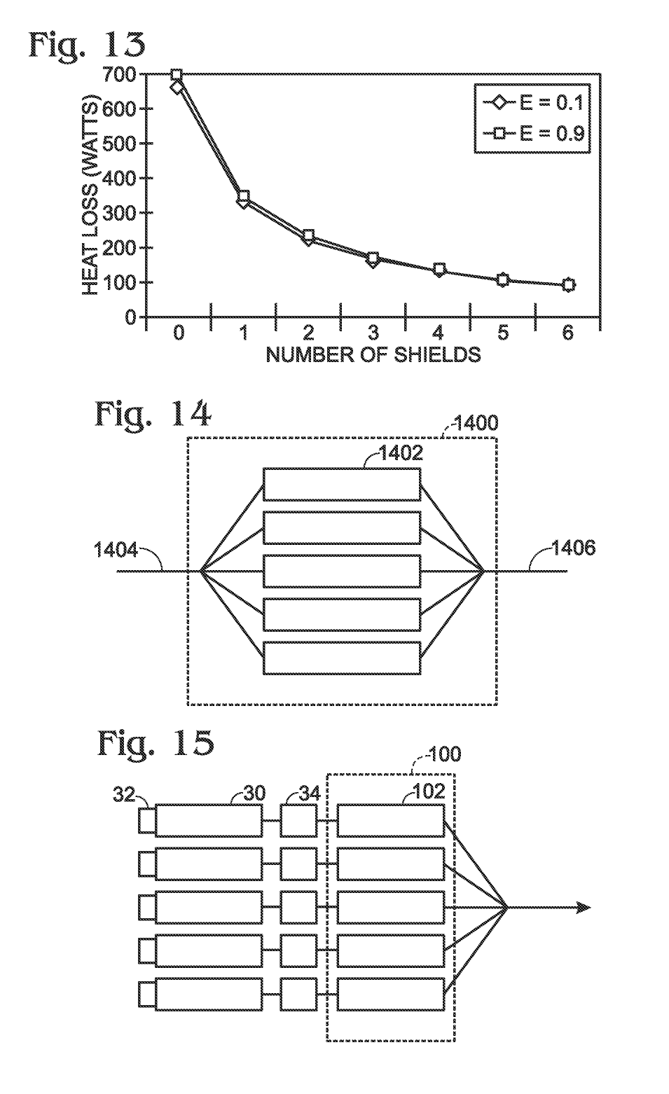

Using the above methodology, the outer surface temperature T₂, for a number of shields from 0 to 6 were calculated. The results are shown in Table 1 below, and are graphically demonstrated in FIG. 11.

TABLE 1

| Number of | Surface temperature | Surface temperature |
|---|---|---|
| radiation shields | (° C.; ε₀ = 0.1) | (° C.; ε₀ = 0.9) |
| 0 | 227 | 147 |
| 1 | 144 | 98 |
| 2 | 112 | 78 |
| 3 | 94 | 66 |
| 4 | 82 | 59 |
| 5 | 74 | 54 |
| 6 | 67 | 50 |

The corresponding heat losses through insulating structure 900 are shown in Table 2 below, and graphically in FIG. 12.

TABLE 2

| Number of | Heat loss | Heat loss |
|---|---|---|
| radiation shields | (W; ε₀ = 0.1) | (W; ε₀ = 0.9) |
| 0 | 661 | 692 |
| 1 | 331 | 343 |
| 2 | 219 | 226 |
| 3 | 163 | 168 |
| 4 | 129 | 132 |
| 5 | 106 | 109 |
| 6 | 90 | 92 |

From these data, it can be seen that an insulating structure may be constructed to provide a desired surface temperature and amount of heat loss by selecting an appropriate number of and configuration of radiation shields 910, as well as suitable inner wall 902 and outer wall 904 material. Furthermore, it can be seen that the use of a higher emissivity material for outer wall 904 may lead to a lower surface temperature but higher amount of heat loss relative to the use of a lower emissivity material.

As mentioned above, reactor system 100 may have other inlet and/or outlet configurations than that shown in FIG. 2. FIGS. 14 and 15 show alternate embodiments of inlet, outlet and precursor source configurations. First referring to FIG. 14, reactor system 1400 includes five individual reactor passageways 1402, and a single inlet 1404 and outlet 1406 to which all five individual reactor passageways 1402 are connected via internal structures of reactor 1400. It will be appreciated that a reactor may also have one inlet and a plurality of outlets, or one outlet and a plurality of inlets. Furthermore, a reactor may also have an inlet and/or an outlet connected to more than one, but not all, reactor passages. For example, a reactor having four reactor passages may include two inlets and/or outlets that each connects to two reactor passages, or one inlet and/or outlet that connects to one reactor passage and another that connects to the other three reactor passages, etc.

Next, FIG. 15 shows reactor system 100 with an alternate precursor source configuration. In this Figure, each reactor passage 102 of reactor system 100 is connected to a separate precursor source 30 (each having its own heater 32), and vapor flow controller 34. In other embodiments, more than one but less than five precursor sources may be used, wherein each precursor source provides precursor to a subset of the reactor passages. It will be appreciated that any suitable number of precursor sources may be used to provide a flow of precursor vapor to reactor system 100, including two or more precursor sources for each reactor passage.

It will be appreciated that the reactor system embodiments disclosed herein are exemplary in nature, and that these specific embodiments are not to be considered in a limiting sense, because numerous variations are possible. The subject matter of the present disclosure includes all novel and non-obvious combinations and subcombinations of the various reactor bodies, heater bodies, heaters, inlet and outlet systems, reactor chemistries, and other features, functions and/or properties disclosed herein.

The following claims particularly point out certain combinations and subcombinations regarded as novel and nonobvious. These claims may refer to “an” element or “a first” element or the equivalent thereof. Such claims should be understood to include incorporation of one or more such elements, neither requiring nor excluding two or more such elements. Other combinations and subcombinations of the reactor bodies, heater bodies, heaters, inlet and outlet systems and configurations, reactor chemistries, and/or other features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

What is claimed is:

1. A reactor system for removing a leaving group from a gas-phase precursor to form a gas-phase radical species for transport polymerization, the reactor system comprising:
a reactor body;
a plurality of reactor passages extending at least partially through the reactor body; and
a heater body disposed in each reactor passage.

2. The reactor system of claim 1, wherein each heater body is substantially thermally conductively insulated from the reactor body.

3. The reactor system of claim 1, wherein each heater body includes a plurality of fins extending radially from a central core, wherein an outer edge of each fin is spaced from an inner wall of an associated reactor passage.

4. The reactor system of claim 1, wherein the reactor body is generally cylindrical in shape and comprises a cylindrical axis, and wherein each reactor passage comprises a generally cylindrical passage extending through the reactor body along a direction of the cylindrical axis.

5. The reactor system of claim 1, further comprising a heater disposed in the reactor body, wherein the heater is positioned adjacent to a corresponding reactor passage.

6. The reactor system of claim 5, further comprising a plurality of heaters, wherein each heater is positioned adjacent to a corresponding reactor passage.

7. The reactor system of claim 1, further comprising an insulating structure substantially surrounding the reactor body, wherein the insulating structure comprises an inner wall, an outer wall, and at least one radiation shield disposed between and spaced from the inner wall and the outer wall.

8. The reactor system of claim 7, wherein the at least one radiation shield is made substantially completely of a material having an emissivity of 0.1.

9. The reactor system of claim 7, further comprising a space between the inner wall and the outer wall, and a vacuum fitting in fluid communication with the space to allow a reduction of a pressure within the space.

10. The reactor system of claim 1, wherein each reactor passage includes an inner surface, and wherein at least one of the inner surfaces of the reactor passages and the heater bodies comprises a material that is chemically reactive with the leaving group.

11. The reactor system of claim 10, wherein the material that is chemically reactive with the leaving group comprises at least one of Ti, Cr, Fe, Co, Ni, Cu, Zn, Ta, W, Pt, Au, and Ag.

12. A reactor system for forming a gas-phase radical intermediate from a gas-phase precursor for a transport polymerization process, the reactor system comprising:
a reactor body;
a plurality of reactor passages disposed in the reactor body, each reactor passage extending at least partially through the reactor body;
a heater body disposed in each reactor passage, wherein each heater body is substantially thermally conductively insulated from the reactor body; and
at least one heater disposed within the reactor body.

13. The reactor system of claim 12, wherein each heater body includes a plurality of fins extending radially from a central core, wherein an outer edge of each fin is spaced from an inner wall of an associated reactor passage.

14. The reactor system of claim 12, wherein the reactor body is generally cylindrical in shape and comprises a cylindrical axis, and wherein each reactor passage comprises a generally cylindrical passage extending through the reactor body along a direction of the cylindrical axis.

15. The reactor system of claim 12, further comprising a plurality of heaters disposed within the reactor body, wherein each heater is adjacent to a corresponding reactor passage.

16. The reactor system of claim 12, further comprising an insulating structure substantially surrounding the reactor body, wherein the insulating structure comprises an inner wall, an outer wall, and at least one radiation shield disposed between and spaced from the inner wall and the outer wall.

17. The reactor system of claim 16, wherein the radiation shield is made substantially completely of a material having an emissivity of approximately 0.1.

18. The reactor system of claim 16, further comprising a space between the inner wall and the outer wall, and a vacuum fitting in fluid communication with the space.

19. The reactor system of claim 12, wherein each reactor passage includes an inner surface, and wherein the inner surfaces of the reactor passages and the heater bodies comprise a material that is chemically reactive with the leaving group.

20. The reactor system of claim 19, wherein the material that is chemically reactive with the leaving group comprises at least one of Ti, Cr, Fe, Co, Ni, Cu, Zn, Ta, W, Pt, Au, and Ag.

21. A reactor system for forming a gas-phase radical species via the removal of a leaving group from a gas-phase precursor species, the reactor system comprising:
a reactor body;
at least one reactor passage extending at least partially through the reactor body;
a heater body disposed within the reactor passage; and
an insulating structure substantially surrounding the reactor body, the insulating structure comprising an inner wall, an outer wall, a vacuum space between the inner wall and the outer wall, and at least one low emissivity radiation barrier disposed in the vacuum space between the inner wall and the outer wall.

22. The reactor system of claim 21, wherein the heater body is substantially thermally conductively insulated from the reactor body.

23. The reactor system of claim 21, wherein the heater body includes a plurality of fins extending radially from a central core, and wherein an outer edge of each fin is spaced from an inner wall of the reactor passage.

24. The reactor system of claim 21, wherein the radiation barrier is spaced from the outer wall.

25. The reactor system of claim 21, further comprising a heater disposed in the reactor body, wherein the heater is adjacent to a corresponding reactor passage.

26. The reactor system of claim 21, wherein the radiation barrier is made substantially completely of a material having an emissivity of approximately 0.1.

27. The reactor system of claim 21, wherein the insulating structure further comprises a plurality of low emissivity radiation barriers disposed in the vacuum space.

28. The reactor system of claim 21, wherein the plurality of low emissivity radiation barriers are arranged in a spaced-apart relation along a radial direction of the insulating structure.

29. The reactor system of claim 21, wherein the reactor passage includes an inner surface, and wherein at least one of the inner surface of the reactor passage and the heater body comprises a material that is chemically reactive with the leaving group.

30. The reactor system of claim 29, wherein the material that is chemically reactive with the leaving group comprises at least one of Ti, Cr, Fe, Co, Ni, Cu, Zn, Ta, W, Pt, Au, and Ag.

31. The reactor system of claim 21, wherein the insulating structure further comprises an outer surface made at least partially of a material with an emissivity of approximately 0.9.
